(19) United States
(12) Patent Application Publication
(10) Pub. No.: US 2026/0093863 A1
(43) Pub. Date: Apr. 2, 2026

(54) BOND-BASED PERIDYNAMICS NUMERICAL SIMULATION METHOD ANDSYSTEM, DEVICE, AND MEDIUM

(71) Applicant: Sun Yat-sen University, Guangzhou (CN)

(72) Inventors: Dingfeng CAO, Guangzhou (CN); Zhixia LIU, Guangzhou (CN); Chengchao GUO, Guangzhou (CN); Fuming WANG, Guangzhou (CN); Baosong MA, Guangzhou (CN); Fan YANG, Guangzhou (CN); Lei QIN, Guangzhou (CN)

(21) Appl. No.: 18/999,805

(22) Filed: Dec. 23, 2024

(30) Foreign Application Priority Data
Sep. 27, 2024 (CN) 202411359150.1

(51) Int. Cl. G06F 30/17

(52) U.S. Cl. CPC G06F 30/17

(57) ABSTRACT

A Weibull function is used to randomly assign the linear elastic limit bond stretch and tensile limit bond stretch of each material point of a material to be analyzed after a quantitative discrete processing is performed on the material to be analyzed; based on the discrete processing result, relative position vector, relative displacement vector, bond stiffness, and a bond stretch of any two material points in a group are sequentially calculated, and a bilinear damage function and a bond-based peridynamics constitutive equation are constructed; based on the constitutive equation, the coordinate information of each material point and the bond stretch are cyclically updated time step by time step bond stretch and a value of the bilinear damage function is obtained, and the group information is updated; a local damage value of each material point is calculated to analyze the fracture situation and obtain the damage determination result.

### CROSS-REFERENCE TO RELATED APPLICATION

The present application claims priority to Chinese Patent Application No. 2024113591501, filed with the China National Intellectual Property Administration (CNIPA) on Sep. 27, 2024, the disclosure of which is incorporated herein by reference in its entirety.

### TECHNICAL FIELD

The present invention relates to the field of mechanical engineering technology, in particular, a bond-based peridynamics numerical simulation method and system, a device, and a medium.

### BACKGROUND

In the field of materials engineering, bond-based peridynamics numerical simulation is used to study key mechanical properties of materials such as a failure mechanism, fracture toughness, and fatigue life. By simulating the deformation and failure processes of materials under different loading conditions, researchers can gain a deeper understanding of how the microstructure of materials influences their macroscopic mechanical behavior.

Bond-based peridynamics theory is an important branch of peridynamics (PD) theory. Bond-based peridynamics theory establishes a model based on the concept of non-local interactions and describes the mechanical behavior of materials by solving spatial integral equations. Bond-based peridynamics theory discretizes materials into multiple material points and uses the positions of these points to describe the interactions between points. Existing bond-based peridynamics numerical simulation methods are based on elastic-brittle models of force and deformation. Specifically, the relationship between distance and force between two material points fully follows the elastic relationship when the distance between the two points is less than a certain value. However, when the distance exceeds a certain value, it is considered that the interaction force between the material points disappears, that is, the bond is completely fractured.

However, existing bond-based peridynamics theories define the fracture parameters of all the material points in the study object with a fixed value. Therefore, the existing bond-based peridynamics theories are suitable for homogeneous elastic-brittle materials. Cement-stabilized materials, which are mixtures of sand, gravel, and cement, are heterogeneous materials. Hence, cement-stabilized materials are quasi-brittle heterogeneous materials. Existing bond-based peridynamics numerical simulation methods are not suitable for analyzing and simulating the fracture behavior of quasi-brittle heterogeneous materials.

It can be seen that how to solve the problem that the existing bond-based peridynamics numerical simulation methods are not suitable for simulating the fracture behavior of quasi-brittle heterogeneous materials has become an urgent technical problem to be addressed by those skilled in the art.

### SUMMARY

The present invention provides a bond-based peridynamics numerical simulation method and system, a device, and a medium to solve the technical problem that the existing bond-based peridynamics numerical simulation methods are not suitable for simulating the fracture behavior of quasi-brittle heterogeneous materials. The present invention aims to provide a method that is applicable to the fracture behavior analysis of quasi-brittle heterogeneous materials so as to achieve accurate simulation of the fracture behavior of quasi-brittle heterogeneous materials.

In a first aspect, the present invention provides a bond-based peridynamics numerical simulation method. The method is applied to simulating fracture behavior of a quasi-brittle heterogeneous material. The method includes the steps below.

During a process of material damage determination, quantitative discrete information of a material to be analyzed is acquired, where the quantitative discrete information includes respective coordinate information, respective volume information, and respective group information of each material point.

By using the Weibull function, a linear elastic limit bond stretch of each material point and a tensile limit bond stretch of each material point are randomly assigned to obtain a fracture parameter matrix.

Based on the coordinate information, relative position vector, relative displacement vector, bond stiffness, and a bond stretch of any two material points in a group are sequentially calculated, and a bilinear damage function is constructed based on the fracture parameter matrix and the bond stretch.

A bond-based peridynamics constitutive equation is constructed based on the relative position vector, the relative displacement vector, the bond stretch, the bond stiffness, and the bilinear damage function.

Within a preset total number of computational time steps, the coordinate information of each material point is cyclically updated time step by time step based on the bond-based peridynamics constitutive equation, the volume information, and the group information, and a corresponding bond stretch is updated based on cyclically updated coordinate information to obtain a respective updated bond stretch of each material point.

The updated bond stretch is substituted into the bilinear damage function to obtain a value of the bilinear damage function, and the group information is updated based on the value of the bilinear damage function to obtain updated group information.

A respective local damage value of each material point is calculated based on the updated group information, a damage and fracture state of the material to be analyzed at a corresponding time step is obtained based on the local damage value, and computation is completed for the preset total number of computational time steps through iterative looping to obtain a bond-based peridynamics simulation result for damage and fracture behavior of the material to be analyzed.

Preferably, acquiring the quantitative discrete information of the material to be analyzed includes the steps below.

Numerical values of mechanical parameters required for bond-based peridynamics numerical simulation are acquired, where the mechanical parameters at least include elastic modulus, density, Poisson's ratio, geometric dimension, and material point size of the material to be analyzed.

A quantitative discrete processing is performed on the material to be analyzed based on the material point size to obtain the coordinate information and the volume information of each material point.

For each material point, neighboring material points within a predefined domain radius are designated as a respective group of each material point, and group information of the respective group is acquired and stored.

Preferably, randomly assigning, by using the Weibull function, the linear elastic limit bond stretch of each material point and the tensile limit bond stretch of each material point to obtain the fracture parameter matrix includes the steps below.

A first matrix of the same size as the number of material points is constructed, and the first matrix is randomly assigned using the Weibull function.

An experimental value of a linear elastic limit bond stretch and an experimental value of a tensile limit bond stretch of the material to be analyzed are acquired, the product of a randomly assigned first matrix and the experimental value of the linear elastic limit bond stretch is taken as a linear elastic limit bond stretch matrix of each material point, and the product of the randomly assigned first matrix and the experimental value of the tensile limit bond stretch is taken as a tensile limit bond stretch matrix of each material point.

The linear elastic limit bond stretch matrix and the tensile limit bond stretch matrix are taken as a fracture parameter matrix.

Preferably, based on the coordinate information, sequentially calculating the relative position vector, the relative displacement vector, the bond stiffness, and the bond stretch of the any two material points and constructing the bilinear damage function based on the fracture parameter matrix and the bond stretch include the steps below.

The relative position vector, the relative displacement vector, and the bond stiffness between the any two material points are calculated based on initial coordinate information.

The expression of the relative position vector is as follows:

$$ξ = {x}_{j} - {x}_{i} .$$

In the formula, xⱼ denotes coordinates of a material point), and xᵢ denotes coordinates of a material point i.

The expression of the relative displacement vector is as follows:

$$η = u ( {x}_{j} , t ) - u ( {x}_{i} , t ) .$$

In the formula, u(xⱼ,t) denotes displacement vector of the material point j at a time step t, and u(xⱼ,t) denotes displacement vector of the material point i at the time step t.

The expression of the bond stiffness is as follows:

$$c = \{ \begin{matrix}\frac{12 E}{{πδ}^{\text{?}}} & three - dimensional condition \\ \frac{9 E}{{πδ}^{\text{?}}} & plane stress condition \\ \frac{48 E}{5 {πδ}^{\text{?}}} & plane strain condition \\ \frac{2 E}{A {δ}^{\text{?}}} & one - dimensional condition\end{matrix} .$$

$$\text{?} \text{indicates text missing or illegible when filed}$$

E denotes elastic modulus, and δ denotes a domain radius.

The bond stretch is calculated based on the relative position vector and relative displacement vector, where the expression of the bond stretch is as follows:

$$s = \frac{‖ ξ + η ‖ - ‖ ζ ‖}{‖ ξ ‖} .$$

The bilinear damage function is constructed based on the linear elastic limit bond stretch of each material point and the tensile limit bond stretch of each material point in the fracture parameter matrix and the bond stretch, where the bilinear damage function is as follows:

$$D = \{ \begin{matrix}1 & 0 < s \leq {s}_{p} \\ \frac{Δ OFB}{Δ OAB} & {s}_{p} < s \leq {s}_{r} \\ 0 & {s}_{r} < s\end{matrix} .$$

In the formula, sₚ denotes the linear elastic limit bond stretch of each material point, sᵣ denotes the tensile limit bond stretch of each material point, ΔOFB denotes the area of a triangle composed of an unloading path after damage, a continuous loading path after damage, and the tensile limit bond stretch in a damage fracture process, and ΔOAB denotes the area of a triangle composed of a loading and unloading path in an elastic stage, the continuous loading path after damage, and the unloading path after damage in the damage fracture process.

Preferably, the bond-based peridynamics constitutive equation is as follows:

$$f ( η , ξ ) = Dc ( 0 , δ ) s \frac{ξ + η}{\vert ξ + η \vert} .$$

In the formula, D denotes the bilinear damage function, ξ denotes the relative position vector, η denotes the relative displacement vector, δ denotes the domain radius, s denotes the bond stretch, and c(0,δ) denotes the bond stiffness.

Preferably, cyclically updating the coordinate information of each material point time step by time step based on the bond-based peridynamics constitutive equation, the volume information, and the group information and updating the corresponding bond stretch based on the cyclically updated coordinate information to obtain the respective updated bond stretch of each material point include the steps below.

Based on the bond-based peridynamics constitutive equation, acceleration of each material point at each time step is calculated, and velocity and displacement of each material point at each time step are calculated based on the acceleration.

The expression of the acceleration at each time step is as follows:

$$ρ a ( t ) = ρ \frac{{\partial }^{2} u ( {x}_{i} , t )}{\partial {t}^{2}} = {\int }_{{H}_{i}} f ( u ( {x}_{j} , t ) - u ( {x}_{j} , t ) , {x}_{j} - x , ) {dV}_{j} + b ( {x}_{i} , t ) .$$

In the formula, β denotes mass density, a(t) denotes acceleration of the material point i at the time step t, f denotes a force function obtained by solving the bond-based peridynamics constitutive equation, f(u(xⱼ,t)−u(xⱼ,t), xⱼ−xᵢ) denotes a force applied by the material point i to the material point j at the time step t, Vⱼ denotes the volume of the material point j, Hᵢ denotes the group of the material point i, and b(xᵢ,t) denotes external force density of the material point i at the time step t.

The expression of the velocity at each time step is as follows:

$$v ( t ) = {v}_{t - 1} + a ( t ) dt .$$

In the formula, vᵢ₋₁ denotes velocity at a time step t−1.

The expression of the displacement at each time step is as follows:

$$u ( t ) = {u}_{t - 1} + v ( t ) dt .$$

In the formula, uₜ₋₁ denotes velocity at the time step t−1.

Based on the velocity at each time step and the displacement at each time step, the coordinate information of each material point is updated.

Based on the updated coordinate information, the relative position vector is updated according to the expression of the relative position vector, and the relative displacement vector is updated according to the expression of the relative displacement vector.

Based on updated relative position vector and updated relative displacement vector, the bond stretch is updated according to the expression of the bond stretch to obtain the respective updated bond stretch of each material point.

Preferably, updating the group information based on the value of the bilinear damage function includes the following:

In the case where the value of the bilinear damage function is not equal to 0, the group information is not updated.

In the case where the value of the bilinear damage function is equal to 0, the any two material points are mutually removed from each other's group information.

In a second aspect, the present invention also provides a bond-based peridynamics numerical simulation system. The system includes a discrete parameter acquisition unit, a fracture parameter matrix acquisition unit, a loss function construction unit, a constitutive equation construction unit, a bond stretch update unit, a group information update unit, and a damage determination unit.

The discrete parameter acquisition unit is configured to acquire, during a process of material damage determination, quantitative discrete information of a material to be analyzed, where the quantitative discrete information includes respective coordinate information, respective volume information, and respective group information of each material point.

The fracture parameter matrix acquisition unit is configured to randomly assign, by using a Weibull function, a linear elastic limit bond stretch of each material point and a tensile limit bond stretch of each material point to obtain a fracture parameter matrix.

The loss function construction unit is configured to: based on the coordinate information, sequentially calculate relative position vector, relative displacement vector, bond stiffness, and a bond stretch of any two material points in a group and construct a bilinear damage function based on the fracture parameter matrix and the bond stretch.

The constitutive equation construction unit is configured to construct a bond-based peridynamics constitutive equation based on the relative position vector, the relative displacement vector, the bond stretch, the bond stiffness, and the bilinear damage function.

The bond stretch update unit is configured to: within a preset total number of computational time steps, cyclically update the coordinate information of each material point time step by time step based on the bond-based peridynamics constitutive equation, the volume information, and the group information, and update a corresponding bond stretch based on cyclically updated coordinate information to obtain a respective updated bond stretch of each material point.

The group information update unit is configured to substitute the updated bond stretch into the bilinear damage function to obtain a value of the bilinear damage function and update the group information based on the value of the bilinear damage function to obtain updated group information.

The damage determination unit is configured to calculate a respective local damage value of each material point based on the updated group information, obtain a damage and fracture state of the material to be analyzed at a corresponding time step based on the local damage value, and complete computation for the preset total number of computational time steps through iterative looping to obtain a bond-based peridynamics simulation result for damage and fracture behavior of the material to be analyzed.

In a third aspect, the present invention also provides a computing device. The device includes a memory, a processor, and a transceiver, which are interconnected via a bus. The memory is configured to store a set of computer program instructions and data and transmit stored data to the processor. The processor executes the program instructions stored in the memory to perform the preceding bond-based peridynamics numerical simulation method.

In a fourth aspect, the present invention also provides a non-transitory computer-readable storage medium storing a computer program that, when executed, performs the preceding bond-based peridynamics numerical simulation method.

The present invention provides a bond-based peridynamics numerical simulation method and system, a device, and a medium. Compared to the existing art, the beneficial effects of the embodiments of the present invention include at least one of the following:

1. As for the characteristics of quasi-brittle heterogeneous materials, a method suitable for analyzing the fracture behavior of the quasi-brittle heterogeneous materials is provided to improve the accuracy of predicting the fracture positions of cement-stabilized materials.

2. The load-displacement curve obtained through the bond-based peridynamics numerical simulation method can predict the experimental result of a material under analysis, reflecting the strain-softening characteristics of the material to be analyzed.

### BRIEF DESCRIPTION OF DRAWINGS

FIG. 1 is a diagram illustrating the steps of a bond-based peridynamics numerical simulation method according to a preferred embodiment of the present invention.

FIG. 2 is a diagram illustrating the steps of a quantitative discrete method according to a preferred embodiment of the present invention.

FIG. 3 is a diagram illustrating the interaction between discrete material points according to a preferred embodiment of the present invention.

FIG. 4 is a diagram illustrating the steps of a method for acquiring a fracture parameter matrix according to a preferred embodiment of the present invention.

FIG. 5 is a diagram of a bilinear damage function according to a preferred embodiment of the present invention.

FIG. 6 is a diagram of the loading positions for a four-point bending cement-stabilized gravel beam specimen according to a preferred embodiment of the present invention.

FIG. 7 is a diagram showing the comparison between damage cloud map at different time steps during the fracture process of a cement-stabilized gravel beam specimen and an actual fracture photograph of the material after testing according to a preferred embodiment of the present invention.

FIG. 8 is a diagram showing the comparison between the displacement-load curve numerical results and experimental results obtained from a test according to a preferred embodiment of the present invention.

FIG. 9 is a diagram illustrating the structure of a bond-based peridynamics numerical simulation system according to a preferred embodiment of the present invention.

FIG. 10 is a diagram of a computer device according to a preferred embodiment of the present invention.

### DETAILED DESCRIPTION

The embodiments of the present invention are described in conjunction with the accompanying drawings. The embodiments are provided for illustrative purposes only and are not to be construed as limitations of the present invention. The accompanying drawings are provided for reference and illustration only and do not constitute limitations on the scope of the present invention. Based on the embodiments of the present invention, all other embodiments acquired by those skilled in the art are within the scope of the present invention on the premise that no creative work is done. In the description of the present invention, terms such as “first”, “second”, and “third” are for description only and are not to be construed as indicating or implying relative importance or implicitly indicating the number of technical features as indicated. Thus, features defined as “first”, “second”, “third”, and the like may explicitly or implicitly include one or more of the features. In the description of the present invention, unless otherwise noted, “a plurality of” means two or more.

In the description of the present invention, it should be noted that unless otherwise expressly specified and limited, terms such as “mounted”, “connected to each other”, and “connected” are to be construed in a broad sense, for example, as permanently connected, detachably connected, or integrally connected: mechanically connected or electrically connected; directly connected or indirectly connected via an intermediate medium; or internally connected of two elements. The terms “vertical”, “horizontal”, “left”, “right”, “up”, “down”, and similar expressions used herein are for illustrative purposes only and do not indicate or imply that the referred apparatus or element has a specific orientation and is constructed and operated in a specific orientation, and thus it is not to be construed as limiting the present invention. The term “and/or” used herein includes any or all combinations of one or more listed associated items. For those of ordinary skill in the art, specific meanings of the preceding terms in the present invention may be understood based on specific situations.

In the description of the present invention, it should be noted that unless otherwise defined, all technical and scientific terms used in the present invention have the same meanings as the terms commonly understood by those skilled in the art. The terms used in the specification of the present invention are only for the purpose of describing specific embodiments and are not intended to limit the present invention. For those of ordinary skill in the art, specific meanings of the preceding terms in the present invention can be construed depending on specific contexts.

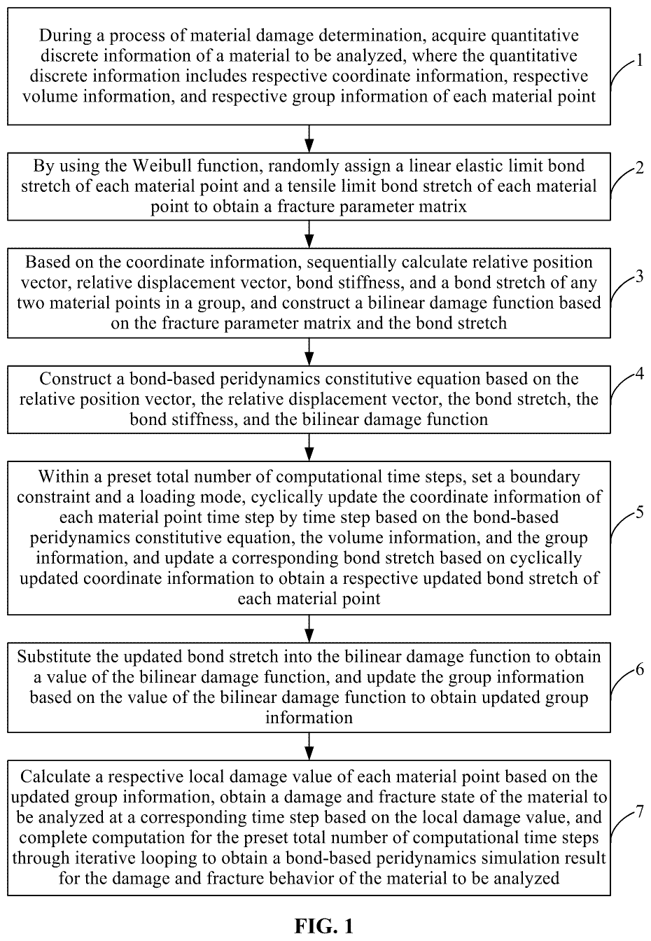

With reference to FIG. 1, a bond-based peridynamics numerical simulation method is provided in an embodiment of the present invention. The method is applied to simulating the fracture behavior of a quasi-brittle heterogeneous material. The method includes S1 to S7.

In S1, during a process of material damage determination, quantitative discrete information of a material to be analyzed is acquired, where the quantitative discrete information includes respective coordinate information, respective volume information, and respective group information of each material point.

In S2, by using the Weibull function, a linear elastic limit bond stretch of each material point and a tensile limit bond stretch of each material point are randomly assigned to obtain a fracture parameter matrix.

In S3, based on the coordinate information, relative position vector, relative displacement vector, bond stiffness, and a bond stretch of any two material points in a group are sequentially calculated, and a bilinear damage function is constructed based on the fracture parameter matrix and the bond stretch.

In S4, a bond-based peridynamics constitutive equation is constructed based on the relative position vector, the relative displacement vector, the bond stretch, the bond stiffness, and the bilinear damage function.

In S5, within a preset total number of computational time steps, the coordinate information of each material point is cyclically updated time step by time step based on the bond-based peridynamics constitutive equation, the volume information, and the group information, and a corresponding bond stretch is updated based on cyclically updated coordinate information to obtain a respective updated bond stretch of each material point.

In S6, the updated bond stretch is substituted into the bilinear damage function to obtain a value of the bilinear damage function, and the group information is updated based on the value of the bilinear damage function to obtain updated group information.

In S7, a respective local damage value of each material point is calculated based on the updated group information, a damage and fracture state of the material to be analyzed at a corresponding time step is obtained based on the local damage value, and computation is completed for the preset total number of computational time steps through iterative looping to obtain a bond-based peridynamics simulation result for the damage and fracture behavior of the material to be analyzed.

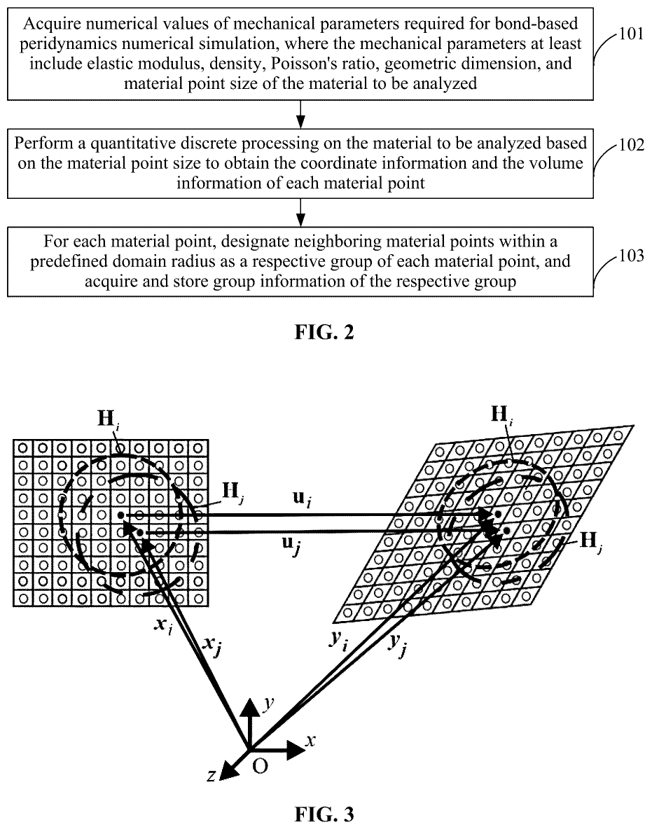

In a preferred embodiment of the present invention, a bond-based peridynamics numerical simulation method suitable for a cement-stabilized material is provided. For the characteristics of quasi-brittle heterogeneous materials, the method discretizes the material to be analyzed into a series of material points and acquires the quantitative discrete information of the material to be analyzed. The quantitative discrete information includes the respective coordinate information, respective volume information, and respective group information of each material point, as shown in FIG. 2. The method includes the steps below.

In S101, numerical values of mechanical parameters required for bond-based peridynamics numerical simulation are acquired, where the mechanical parameters at least include elastic modulus, density, Poisson's ratio, geometric dimension, and material point size of the material to be analyzed.

In S102, a quantitative discrete processing is performed on the material to be analyzed based on the material point size to obtain the coordinate information and the volume information of each material point.

In S103, for each material point, neighboring material points within a predefined domain radius are designated as a respective group of each material point, and group information of the respective group is acquired and stored.

In the preferred embodiment of the present application, numerical values of mechanical parameters required for bond-based peridynamics numerical simulation are acquired. These parameters specifically include elastic modulus E of the material, the density p, the Poisson's ratio v, the geometric dimension of the object under study, the material point size dx, and the total number of computational time steps nt.

The material to be analyzed is discretized into a series of material points with a diameter of dx based on the material point size, and the coordinate information and volume information of each material point are obtained. As shown in FIG. 3, FIG. 3 is a diagram illustrating the interaction between discrete material points. Hᵢ denotes the neighborhood material points of the material point i in the object under study, that is, the group of the material point i, and the neighborhood radius is δ. The neighborhood radius δ is a positive number. In the preferred embodiment of the present application, the value of δ is set to 3.015 dx, and interaction forces exist between the material point i and its neighboring points. Under three-dimensional conditions, the shape of Hᵢ is assumed to be spherical, while in two-dimensional plane stress and strain problems, the shape of Hᵢ is assumed to be circular.

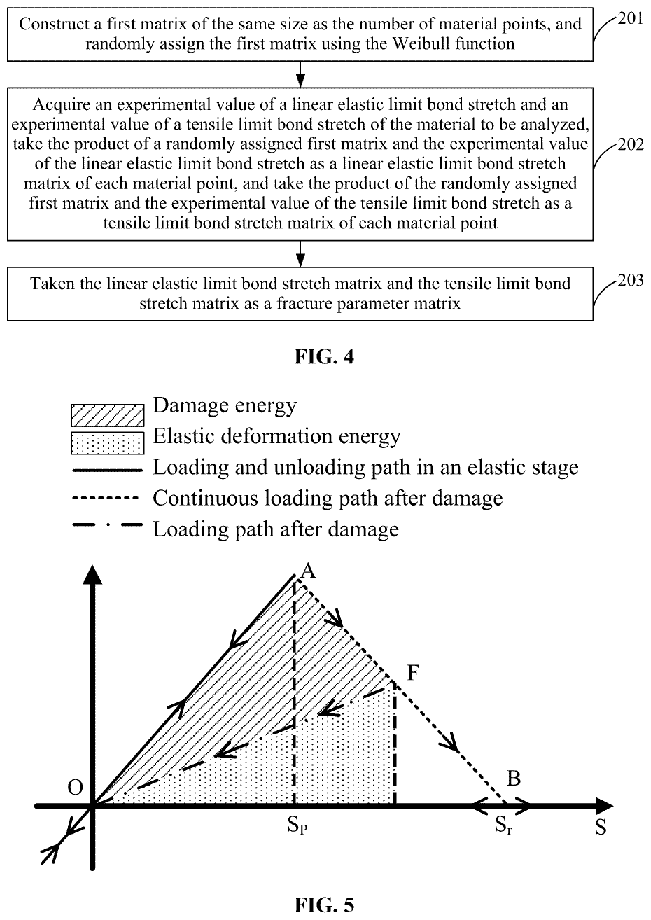

Cement-stabilized materials are quasi-brittle heterogeneous materials, and the damage and fracture process of the materials' bonds may be described using a bilinear damage function. For the characteristics of quasi-brittle heterogeneous materials, the linear elastic limit bond stretch and tensile limit bond stretch are used as the fracture parameters of the material to be analyzed. A Weibull function is used to randomly assign the linear elastic limit bond stretch and tensile limit bond stretch for each material point, and a fracture parameter matrix is obtained. As shown in FIGS. 4, S201 to S203 are included:

In S201, a first matrix of the same size as the number of material points is constructed, and the first matrix is randomly assigned using the Weibull function.

In S202, an experimental value of a linear elastic limit bond stretch and an experimental value of a tensile limit bond stretch of the material to be analyzed are acquired, the product of a randomly assigned first matrix and the experimental value of the linear elastic limit bond stretch is taken as a linear elastic limit bond stretch matrix of each material point, and the product of the randomly assigned first matrix and the experimental value of the tensile limit bond stretch is taken as a tensile limit bond stretch matrix of each material point.

In S203, the linear elastic limit bond stretch matrix and the tensile limit bond stretch matrix are taken as a fracture parameter matrix.

The traditional bond-based peridynamics numerical simulation method assumes that the fracture parameters of all material points are identical, that is, the material is assumed to be homogeneous. However, cement-stabilized materials are mixtures of sand, gravel, and cement and thus are heterogeneous. Therefore, randomly assigning values to the fracture parameters of the material is necessary to reflect the heterogeneous characteristics of quasi-brittle materials. In the preferred embodiment of the present application, a Weibull function is used to randomly assign the linear elastic limit bond stretch and tensile limit bond stretch of each material point, thereby achieving the simulation of the quasi-brittle heterogeneous characteristics of cement-stabilized materials.

The expression of the Weibull function is as follows:

$$p ( e ) = 1 - exp [ - {( e / φ )}^{β} ] .$$

In the formula, e denotes the parameter satisfying the Weibull distribution, φ denotes a scaling factor, which is related to but not equal to the mean value E(e) of e, and β denotes a shape parameter that determines the shape of the distribution curve.

The expression of the mean value E(e) of parameters in the Weibull function is as follows:

$$E ( e ) = φΓ ( 1 + \frac{1}{β} ) .$$

The mean value of the parameters of the Weibull function is set to 1, and the shape parameter β equals 4. Based on the number of material points, a first matrix A of the same size as the number of material points is constructed. The size of the first matrix A is [n×1], where n denotes the total number of material points formed after the material to be analyzed being discretized. The Weibull function is used to randomly assign values to the first matrix.

Further, for the linear elastic limit bond stretch and tensile limit bond stretch of each material point in the present application, the linear elastic limit bond stretch and tensile limit bond stretch of the material to be analyzed are first measured by test and used as the experimental values for the linear elastic limit bond stretch and tensile limit bond stretch of each material point of the material to be analyzed. The product of a randomly assigned first matrix and the experimental value of the linear elastic limit bond stretch is taken as a linear elastic limit bond stretch matrix of each material point, that is, B1(i, 1)=sₚ×A(i, 1). The product of the randomly assigned first matrix and the experimental value of the tensile limit bond stretch is taken as a tensile limit bond stretch matrix of each material point, that is, B₂(i, 1)=sᵣ×A(i, 1).

Further, a boundary condition and a loading mode are defined. Specific boundary conditions include fixed support and hinge support, which are achieved by restricting the displacement of material points at the support positions in different directions. Specific loading modes include displacement loading and external force loading, which are achieved by applying displacement or external force to the material points at the loading positions.

Further, based on the defined boundary condition and loading mode as well as the coordinate information of each material point, relative position vector, relative displacement vector, bond stiffness, and a bond stretch of any two material points in a group are sequentially calculated, and a bilinear damage function is constructed based on the fracture parameter matrix and the bond stretch. Specifically, for each time step, the relative position vector, relative displacement vector, and bond stiffness between any two material points are calculated based on the coordinate information. As the material to be analyzed transitions from its initial state to a deformed state, displacements uᵢ and uⱼ occur for two material points i and) during the entire deformation process. The coordinates of the material points change to yᵢ and yⱼ. The expressions of the relative position vector and relative displacement vector are as follows:

The expression of the relative position vector is as follows:

$$ξ = {x}_{j} - {x}_{i} .$$

In the formula, xⱼ denotes coordinates of a material point j, and xᵢ denotes coordinates of a material point i.

The expression of the relative displacement vector is as follows:

$$η = u ( {x}_{j} , t ) - u ( {x}_{i} , t ) .$$

In the formula, u(xⱼ,t) denotes displacement vector of the material point j at a time step t, and u(xᵢ,t) denotes displacement vector of the material point i at the time step t. The displacement vector u(xᵢ,t) is affected by the interaction forces between the material point i and other material points in the neighborhood Hᵢ.

The expression of the bond stiffness is as follows:

$$c = \{ \begin{matrix}\frac{12 E}{{πδ}^{\text{?}}} & three - dimensional condition \\ \frac{9 E}{{πδ}^{\text{?}}} & plane stress condition \\ \frac{48 E}{5 {πδ}^{\text{?}}} & plane strain condition \\ \frac{2 E}{A {δ}^{\text{?}}} & one - dimensional condition\end{matrix} .$$

$$\text{?} \text{indicates text missing or illegible when filed}$$

E denotes elastic modulus, and δ denotes a domain radius. The bond stiffness is referred to as a bond constant.

Based on the relative position vector and the relative displacement vector, the bond stretch is calculated. The expression of the bond stretch is as follows:

$$s = \frac{‖ ξ + η ‖ - ‖ ζ ‖}{‖ ξ ‖} .$$

The bilinear damage function is constructed based on the linear elastic limit bond stretch of each material point and the tensile limit bond stretch of each material point in the fracture parameter matrix and the bond stretch. The bilinear damage function is as follows:

$$D = \{ \begin{matrix}1 & 0 < s \leq {s}_{p} \\ \frac{Δ OFB}{Δ OAB} & {s}_{p} < s \leq {s}_{r} \\ 0 & {s}_{r} < s\end{matrix} .$$

In the formula, sₚ denotes the linear elastic limit bond stretch of each material point, and sᵣ denotes the tensile limit bond stretch of each material point. As shown in FIG. 5, FIG. 5 is a diagram of a bilinear damage function. ΔOFB denotes the area of a triangle composed of an unloading path after damage, a continuous loading path after damage, and the tensile limit bond stretch in a bond damage fracture process, that is, the area of the triangle OFB in FIG. 5; ΔOAB denotes the area of a triangle composed of a loading and unloading path in an elastic stage, the continuous loading path after damage, and the unloading path after damage in the damage fracture process, that is, the area of the triangle OAB in FIG. 5. In the embodiment of the present invention, the bilinear damage function is used as the determination criterion for the elongation damage fracture of the bonds between material points.

A bond-based peridynamics constitutive equation is constructed based on the relative position vector, the relative displacement vector, the bond stretch, the bond stiffness, and the bilinear damage function. The bond-based peridynamics constitutive equation is as follows:

$$f ( η , ξ ) = D c ( 0 , δ ) s \frac{ξ + η}{\vert ξ + η \vert} .$$

In the formula, D denotes the bilinear damage function, ξ denotes the relative position vector, η denotes the relative displacement vector, δ denotes the domain radius, s denotes the bond stretch, and c(0,δ) denotes the bond stiffness.

In the preferred embodiment of the present application, cyclically updating the coordinate information of each material point time step by time step based on the bond-based peridynamics constitutive equation, the volume information, and the group information and updating the corresponding bond stretch based on the cyclically updated coordinate information to obtain the respective updated bond stretch of each material point include the steps below.

Based on the bond-based peridynamics constitutive equation, acceleration of each material point at each time step is calculated, and velocity and displacement of each material point at each time step are calculated based on the acceleration.

The expression of the acceleration at each time step is as follows:

$$ρ a ( t ) = ρ \frac{{\partial }^{2} u ( {x}_{i} , t )}{\partial {t}^{2}} = {\int }_{{H}_{i}} f ( u ( {x}_{j} , t ) - u ( {x}_{j} , t ) , {x}_{j} - {x}_{i} ) d {V}_{j} + b ( {x}_{i} , t ) .$$

In the formula, a(t) denotes acceleration of the material point i at the time step t, ρ denotes mass density, f denotes a force function obtained by solving the bond-based peridynamics constitutive equation, f(u(xⱼ, t)−u(xⱼ, t), xⱼ−xᵢ) denotes a force applied by the material point i to the material point j at the time step t, Vⱼ denotes the volume of the material point j, Hᵢ denotes a group of the material point i, and b(xᵢ,t) denotes external force density of the material point i at the time step t.

The expression of the velocity at each time step is as follows:

$$v ( t ) = {v}_{t - 1} + a ( t ) dt .$$

In the formula, vₜ₋₁ denotes velocity at the time step t−1.

The expression of the displacement at each time step is as follows:

$$u ( t ) = {u}_{t - 1} + v ( t ) d t .$$

In the formula, uₜ₋₁ denotes velocity at the time step t−1.

Based on the velocity at each time step and the displacement at each time step, the coordinate information of each material point is updated.

After substituting the updated coordinate information into the expression of the relative position vector and the expression of the relative displacement vector, the relative position vector and the relative displacement vector are updated.

The updated relative position vector and the updated relative displacement vector are substituted into the bond stretch to update the bond stretch, thereby obtaining the respective updated bond stretch of each material point.

The updated bond stretch is substituted into the bilinear damage function to calculate the value of the bilinear damage function. Based on the value of the bilinear damage function, it is determined whether the bond stretch between each material point and the neighboring material points of each material point reaches the critical value. If the bond stretch between a material point and a neighboring material point is less than the linear elastic limit bond stretch PP of the material point, the value of the bilinear damage function is 1. The interaction force between the two material points is calculated based on the bond-based peridynamics constitutive equation. It can be seen that when the value of the bilinear damage function is 1, the force between the two material points is not weakened, and no bond damage is caused. If the bond stretch between a material point and a neighboring material point exceeds the linear elastic limit bond stretch sₚ of the material point but remains below the tensile limit bond stretch sᵣ, the value of the bilinear damage function lies between (0, 1). This corresponds to a weakening of the interaction force between the two material points, but no bond fracture occurs, and the bond is in a damaged state. If the bond stretch between a material point and a neighboring material point exceeds the tensile limit bond stretch sᵣ of the material point, the value of the bilinear damage function is 0, and the interaction force between the two material points is 0, indicating bond fracture between the two material points. After bond fracture, the two material points are removed from each other's group, and the group information is updated to obtain the updated group information.

In the iteration of each time step, the interaction forces between material points are recalculated, and the group information of each material point is updated. The cumulative bond fractures eventually lead to the macroscopic damage and failure of the material to be analyzed.

In the preferred embodiment of the present invention, after updating the group information, the local damage value of each material point is calculated based on the updated group information. The local damage is defined as the weighted ratio of the number of neighboring material points with eliminated interaction forces in the group of the material point to the total number of initial neighboring material points in the group of the material point. The specific expression of the local damage value is as follows:

$$φ ( i , t ) = 1 - \frac{{\int }_{{H}_{i}} D ( i , t ) {dV}_{j}}{{\int }_{{H}_{i}} {dV}_{j}} .$$

In the formula, D(i,t) denotes the number of neighboring material points with eliminated interaction forces in the group of the material point i at the time step t.

The calculated local damage value is a constant in the range of [0, 1], where φ=1 indicates that all local bonds of the material to be analyzed are completely broken, that is, the material is completely broken.

The respective local damage value of each material point at each time step of the material to be analyzed are expressed in the form of a contour plot to obtain the overall damage and fracture conditions of the material to be analyzed at different time steps.

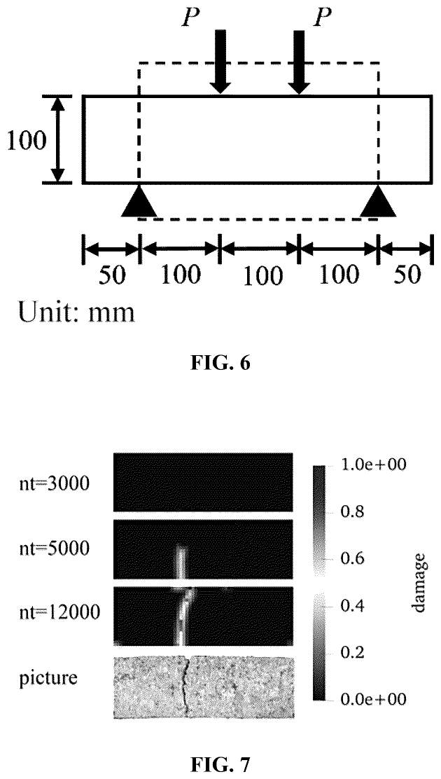

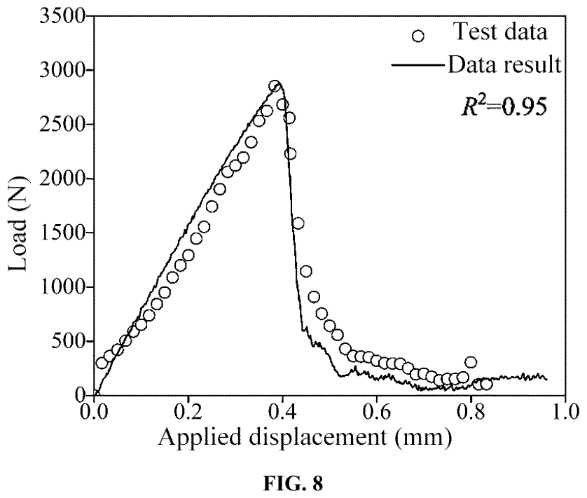

In the preferred embodiment of the present application, the bond-based peridynamics numerical simulation method is validated using the four-point bending process of a cement-stabilized gravel beam as an example. The dimensions of the four-point bending cement-stabilized gravel beam specimen are 400 mm in length, 100 mm in width, and 100 mm in height. The loading mode is displacement control, with a loading speed of 0.1 mm/min. The loading positions are shown in FIG. 6. In the numerical simulation process, three-dimensional analysis is adopted. To reduce the number of material points and improve computational efficiency of the model, only the portion of the cement-stabilized gravel beam specimen subjected to bending moment within the dashed lines is modeled. The simulation parameters are set as follows: Elastic modulus of the material E=4.5 MPa, density ρ=2000 kg/m³, Poisson's ratio υ=1/4, the material point size dx=0.005 m, the total number of computational time steps nt=12000, dt=1, the experimental value of the linear elastic limit bond stretch is 0.00011, and the experimental value of the tensile limit bond stretch is 0.00045. It should be noted that FIG. 6 provides a two-dimensional schematic of the test setup showing the front view of the specimen, while the actual numerical simulation calculation process involves three-dimensional modeling and computation. As shown in FIG. 7, FIG. 7 is a diagram showing the comparison between damage cloud map at different time steps during the fracture process of a cement-stabilized gravel beam specimen and an actual fracture photograph of the material after testing. From FIG. 7, it can be seen that the bond-based peridynamics numerical simulation method of the present invention accurately predicts the fracture locations and crack patterns of the cement-stabilized gravel beam specimen. The bending and deflection of the cracks are related to the heterogeneity of the material. The use of the Weibull function to randomly assign the linear elastic limit bond stretch and tensile limit bond stretch of the material points allows the numerical simulation results to reflect the heterogeneity of the material. FIG. 8 is a diagram showing the comparison between the displacement-load curve numerical results and experimental results obtained from a test. From FIG. 8, it can be seen that the displacement-load curve of the cement-stabilized gravel beam specimen predicted using the bond-based peridynamics numerical simulation method of the present invention fits well with the experimental data. Moreover, the curve exhibits strain-softening characteristics and is consistent with the quasi-brittle nature of cement-stabilized materials.

In the preferred embodiment of the present invention, for the simulation of the fracture behavior of a quasi-brittle heterogeneous material, during a process of material damage determination, quantitative discrete information of a material to be analyzed is acquired, where the quantitative discrete information includes respective coordinate information, respective volume information, and respective group information of each material point; by using the Weibull function, a linear elastic limit bond stretch of each material point and a tensile limit bond stretch of each material point are randomly assigned to obtain a fracture parameter matrix; based on the coordinate information, relative position vector, relative displacement vector, bond stiffness, and a bond stretch of any two material points in a group are sequentially calculated, and a bilinear damage function is constructed based on the fracture parameter matrix and the bond stretch: a bond-based peridynamics constitutive equation is constructed based on the relative position vector, the relative displacement vector, the bond stretch, the bond stiffness, and the bilinear damage function; within a preset total number of computational time steps, the coordinate information of each material point is cyclically updated time step by time step based on the bond-based peridynamics constitutive equation, the volume information, and the group information, and a corresponding bond stretch is updated based on cyclically updated coordinate information to obtain a respective updated bond stretch of each material point: the updated bond stretch is substituted into the bilinear damage function to obtain a value of the bilinear damage function, and the group information is updated based on the value of the bilinear damage function to obtain updated group information: a respective local damage value of each material point is calculated based on the updated group information, and the bond-based peridynamics numerical simulation of the material to be analyzed is performed based on the local damage value to obtain a damage determination result of the material to be analyzed. The bond-based peridynamics numerical simulation method provided by the present invention targets the fracture behavior of quasi-brittle heterogeneous materials and enhances the accuracy of predicting fracture positions in a cement-stabilized material. The load-displacement curve obtained through numerical simulation can predict the experimental results of the material and reflect the strain-softening characteristics of the material.

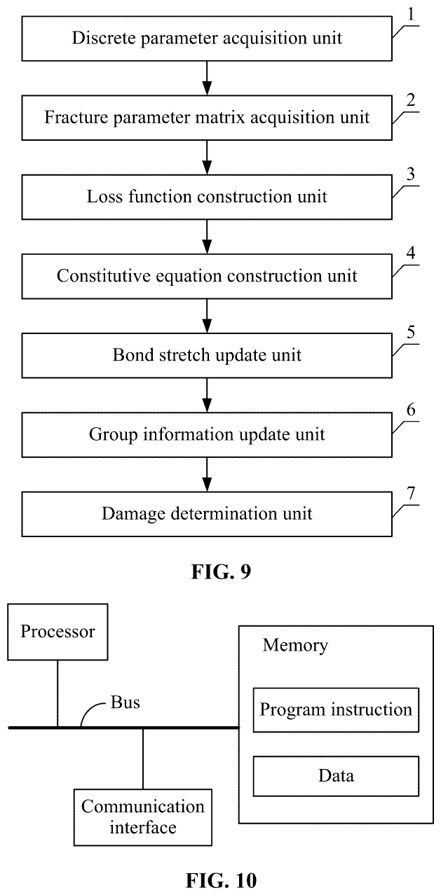

Accordingly, as shown in FIG. 9, based on a bond-based peridynamics numerical simulation method, an embodiment of the present invention also provides a bond-based peridynamics numerical simulation system. The system includes a discrete parameter acquisition unit 1, a fracture parameter matrix acquisition unit 2, a loss function construction unit 3, a constitutive equation construction unit 4, a bond stretch update unit 5, a group information update unit, 6 and a damage determination unit 7.

The discrete parameter acquisition unit 1 is configured to acquire, during a process of material damage determination, quantitative discrete information of a material to be analyzed, where the quantitative discrete information includes respective coordinate information, respective volume information, and respective group information of each material point.

The fracture parameter matrix acquisition unit 2 is configured to randomly assign, by using a Weibull function, a linear elastic limit bond stretch of each material point and a tensile limit bond stretch of each material point to obtain a fracture parameter matrix.

The loss function construction unit 3 is configured to: based on the coordinate information, sequentially calculate relative position vector, relative displacement vector, bond stiffness, and a bond stretch of any two material points in a group and construct a bilinear damage function based on the fracture parameter matrix and the bond stretch.

The constitutive equation construction unit 4 is configured to construct a bond-based peridynamics constitutive equation based on the relative position vector, the relative displacement vector, the bond stretch, the bond stiffness, and the bilinear damage function.

The bond stretch update unit 5 is configured to: within a preset total number of computational time steps, cyclically update the coordinate information of each material point time step by time step based on the bond-based peridynamics constitutive equation, the volume information, and the group information, and update a corresponding bond stretch based on cyclically updated coordinate information to obtain a respective updated bond stretch of each material point.

The group information update unit 6 is configured to substitute the updated bond stretch into the bilinear damage function to obtain a value of the bilinear damage function and update the group information based on the value of the bilinear damage function to obtain updated group information.

The damage determination unit 7 is configured to calculate a respective local damage value of each material point based on the updated group information, obtain a damage and fracture state of the material to be analyzed at a corresponding time step based on the local damage value, and complete computation for the preset total number of computational time steps through iterative looping to obtain a bond-based peridynamics simulation result for damage and fracture behavior of the material to be analyzed.

Specific definitions of a bond-based peridynamics numerical simulation system may be found in the preceding description of definitions of the bond-based peridynamics numerical simulation method. No repetition is made here. Those of ordinary skill in the art may recognize that the various modules and steps described in connection with the embodiments provided in the present invention may be implemented using hardware, software, or a combination of both. Whether these functions are performed in hardware or software depends on the specific application and design constraints of the technical solution. Those skilled in the art may use different methods to implement the described functions for each specific application, but such implementation should not be considered to be beyond the scope of the present invention.

As shown in FIG. 10, a computer device provided in an embodiment of the present invention includes a processor, a memory, and a computer program stored in the memory and executable on the processor. When executing the computer program, the processor implements the steps in the bond-based peridynamics numerical simulation method of the preceding embodiments, such as steps S1 to S7 described in FIG. 1.

It should be understood by those skilled in the art that FIG. 10 is only an example of a computer device and does not limit the computer device, and the computer device may include more or fewer components than those illustrated or may be configured by combining certain components or using different components. For example, the computer device may also include input and output devices, a network access device, a bus, among others.

The processor may be a central processing unit (CPU), a general-purpose processor, a digital signal processor (DSP), an application specific integrated circuit (ASIC), a field-programmable (FPGA), or other programmable logic devices, discrete gates or transistor logic devices, or discrete hardware components. A general-purpose processor may be a microprocessor or any conventional processor. The processor serves as the control center of the computer device and connects various parts of the device through interfaces and circuits.

The memory may store the computer program and/or modules. The processor, by running or executing the computer program and/or modules stored in the memory and invoking the data stored in the memory, achieves various functions of the computer device. The memory may mainly include a program storage region and a data storage region. The program storage region may store an operating system and an application required for at least one function (such as a sound play back function and an image playback function). The data storage region may store data (such as audio data and a phone book) and the like created based on the use of a mobile phone. In addition, the memory may include a high-speed random-access memory (RAM) and a non-volatile memory, such as a hard drive, a memory, a plug-in hard drive, a smart media card (SMC), a secure digital (SD) card, a flash card, at least one magnetic disk storage device, a flash memory device, or other non-volatile solid-state storage devices.

If the module integrated into the computer device is implemented in the form of a software functional unit and sold or used as an independent product, the module may be stored in a computer-readable storage medium. Based on this understanding, all or part of the processes in the preceding method embodiments implemented by the present invention may also be implemented by instructing relevant hardware through a computer program. The computer program may be stored in a computer-readable storage medium, and when executed by a processor, the computer program may perform the steps of the various method embodiments described above. The computer program includes computer program code that may be in the form of source code, object code, executable files, or intermediate forms. The computer-readable medium may include any entity or apparatus capable of carrying the computer program code, a recording medium, a USB drive, a portable hard drive, a magnetic disk, an optical disk, a computer memory, a read-only memory (ROM), a random access memory (RAM), an electrical carrier signal, a telecommunication signal, and a software distribution medium, among others.

Those of ordinary skill in the art may understand that all or part of the processes in the preceding method embodiments can be implemented by instructing related hardware through a computer program. The program may be stored in a computer-readable storage medium. When the program is executed, the processes of the preceding method embodiments may be included. The storage medium may be a magnetic disk, an optical disk, a read-only memory (ROM), a random access memory (RAM), or the like.

Accordingly, an embodiment of the present invention provides a computer-readable storage medium. The medium includes a stored computer program. The computer program, when running, controls the device where the computer-readable storage medium is located to execute the steps in the bond-based peridynamics numerical simulation method of the preceding embodiments, such as steps S1 to S7 described in FIG. 1.

A bond-based peridynamics numerical simulation method and system, a computer device, and a storage medium provided in this embodiment target the technical problem that the existing bond-based peridynamics numerical simulation methods are not suitable for simulating the fracture behavior of quasi-brittle heterogeneous materials. In the present invention, during a process of material damage determination, quantitative discrete information of a material to be analyzed is acquired, where the quantitative discrete information includes respective coordinate information, respective volume information, and respective group information of each material point; by using the Weibull function, a linear elastic limit bond stretch of each material point and a tensile limit bond stretch of each material point are randomly assigned to obtain a fracture parameter matrix; based on the coordinate information, relative position vector, relative displacement vector, bond stiffness, and a bond stretch of any two material points in a group are sequentially calculated, and a bilinear damage function is constructed based on the fracture parameter matrix and the bond stretch: a bond-based peridynamics constitutive equation is constructed based on the relative position vector, the relative displacement vector, the bond stretch, the bond stiffness, and the bilinear damage function; within a preset total number of computational time steps, the coordinate information of each material point is cyclically updated time step by time step based on the bond-based peridynamics constitutive equation, the volume information, and the group information, and a corresponding bond stretch is updated based on cyclically updated coordinate information to obtain a respective updated bond stretch of each material point; the updated bond stretch is substituted into the bilinear damage function to obtain a value of the bilinear damage function, and the group information is updated based on the value of the bilinear damage function to obtain updated group information: a respective local damage value of each material point is calculated based on the updated group information, and the bond-based peridynamics numerical simulation of the material to be analyzed is performed based on the local damage value to obtain a damage determination result of the material to be analyzed. The bond-based peridynamics numerical simulation method provided by the present invention targets the fracture behavior of quasi-brittle heterogeneous materials and enhances the accuracy of predicting fracture positions in a cement-stabilized material. The load-displacement curve obtained through numerical simulation can predict the experimental results of the material and reflect the strain-softening characteristics of the material.

The preceding embodiments are only several preferred embodiments of the present invention, and the specific and detailed description thereof cannot be understood as a limit to the scope of the present invention. It is to be noted that for those skilled in the art, a number of improvements and substitutions may be made without departing from the technical principles of the present invention, and these improvements and substitutions are within the scope of the present invention. Therefore, the scope of the present invention is subject to the scope of the appended claims.

What is claimed is:

1. A bond-based peridynamics numerical simulation method, wherein the method is applied to simulate fracture behavior of a quasi-brittle heterogeneous material, and the method comprises:
during a process of material damage determination, acquiring quantitative discrete information of a material to be analyzed, wherein the quantitative discrete information comprises coordinate information, volume information, and group information of each material point;
randomly assigning, by using a Weibull function, a linear elastic limit bond stretch of each material point and a tensile limit bond stretch of each material point to obtain a fracture parameter matrix;
based on the coordinate information, sequentially calculating relative position vector, relative displacement vector, bond stiffness, and a bond stretch of any two material points in a group, and constructing a bilinear damage function based on the fracture parameter matrix and the bond stretch;
constructing a bond-based peridynamics constitutive equation based on the relative position vector, the relative displacement vector, the bond stretch, the bond stiffness, and the bilinear damage function;
within a preset total number of computational time steps, setting a boundary constraint and a loading mode, cyclically updating the coordinate information of each material point time step by time step based on the bond-based peridynamics constitutive equation, the volume information, and the group information, and updating the bond stretch based on cyclically updated coordinate information to obtain an updated bond stretch of each material point;
substituting the updated bond stretch into the bilinear damage function to obtain a value of the bilinear damage function, and updating the group information based on the value of the bilinear damage function to obtain updated group information; and
calculating a local damage value of each material point based on the updated group information, obtaining a damage and fracture state of the material to be analyzed at a corresponding time step of the preset total number of computational time steps based on the local damage value, and completing computation for the preset total number of computational time steps through iterative looping to obtain a bond-based peridynamics simulation result for damage and fracture behavior of the material to be analyzed.

2. The bond-based peridynamics numerical simulation method according to claim 1, wherein acquiring the quantitative discrete information of the material to be analyzed comprises:
acquiring numerical values of mechanical parameters required for bond-based peridynamics numerical simulation, wherein the mechanical parameters at least comprise elastic modulus, density, Poisson's ratio, geometric dimension, and material point size of the material to be analyzed;
performing a quantitative discrete processing on the material to be analyzed based on the material point size to obtain the coordinate information and the volume information of each material point; and
for each material point, designating neighboring material points within a predefined domain radius as a group of each material point, and acquiring and storing group information of the group.

3. The bond-based peridynamics numerical simulation method according to claim 2, wherein randomly assigning, by using the Weibull function, the linear elastic limit bond stretch of each material point and the tensile limit bond stretch of each material point to obtain the fracture parameter matrix comprises:
constructing a first matrix of a same size as a number of material points, and randomly assigning values to the first matrix using the Weibull function;
acquiring an experimental value of a linear elastic limit bond stretch and an experimental value of a tensile limit bond stretch of the material to be analyzed, taking a product of a randomly assigned first matrix and the experimental value of the linear elastic limit bond stretch as a linear elastic limit bond stretch matrix of each material point, and taking a product of the randomly assigned first matrix and the experimental value of the tensile limit bond stretch as a tensile limit bond stretch matrix of each material point; and
taking the linear elastic limit bond stretch matrix and the tensile limit bond stretch matrix as a fracture parameter matrix.

4. The bond-based peridynamics numerical simulation method according to claim 3, wherein based on the coordinate information, sequentially calculating the relative position vector, the relative displacement vector, the bond stiffness, and the bond stretch of the any two material points in the group and constructing the bilinear damage function based on the fracture parameter matrix and the bond stretch comprise:
calculating the relative position vector, the relative displacement vector, and the bond stiffness between the any two material points based on initial coordinate information;
wherein an expression of the relative position vector is as follows:
$$ξ = {x}_{j} - {x}_{i} ;$$
wherein xⱼ denotes coordinates of a material point j, and xᵢ denotes coordinates of a material point i;
an expression of the relative displacement vector is as follows:
$$η = u ( {x}_{j} , t ) - u ( {x}_{i} , t ) ;$$
wherein u(xⱼ,t) denotes displacement vector of the material point j at a time step t, and u(xᵢ,t) denotes displacement vector of the material point i at the time step t; and
an expression of the bond stiffness is as follows:
$$c = \{ \begin{matrix}\frac{12 E}{{πδ}^{\text{?}}} & three - dimensional condition \\ \frac{9 E}{{πδ}^{\text{?}}} & plane stress condition \\ \frac{48 E}{5 {πδ}^{\text{?}}} & plane strain condition \\ \frac{2 E}{A {δ}^{\text{?}}} & one - dimensional condition\end{matrix} ,$$
$$\text{?} \text{indicates text missing or illegible when filed}$$
E denotes elastic modulus, and δ denotes a domain radius;
calculating the bond stretch based on the relative position vector and relative displacement vector, wherein an expression of the bond stretch is as follows:
$$s = \frac{‖ ξ + η ‖ - ‖ ζ ‖}{‖ ξ ‖} ;$$
and
contracting the bilinear damage function based on the linear elastic limit bond stretch of each material point and the tensile limit bond stretch of each material point in the fracture parameter matrix and the bond stretch, wherein the bilinear damage function is as follows:
$$D = \{ \begin{matrix}1 & 0 < s \leq {s}_{p} \\ \frac{Δ OFB}{Δ OAB} & {s}_{p} < s \leq {s}_{r} \\ 0 & {s}_{r} < s\end{matrix} ;$$
wherein sₚ denotes the linear elastic limit bond stretch of each material point, sᵣ denotes the tensile limit bond stretch of each material point, ΔOFB denotes an area of a triangle composed of an unloading path after damage, a continuous loading path after damage, and the tensile limit bond stretch in a damage fracture process, and ΔOAB denotes an area of a triangle composed of a loading and unloading path in an elastic stage, the continuous loading path after damage, and the unloading path after damage in the damage fracture process.

5. The bond-based peridynamics numerical simulation method according to claim 4, wherein the bond-based peridynamics constitutive equation is as follows:
$$f ( η , ξ ) = Dc ( 0 , δ ) s \frac{ξ + η}{\vert ξ + η \vert} ;$$
wherein D denotes the bilinear damage function, ξ denotes the relative position vector, η denotes the relative displacement vector, δ denotes the domain radius, s denotes the bond stretch, and c(0,δ) denotes the bond stiffness.

6. The bond-based peridynamics numerical simulation method according to claim 5, wherein cyclically updating the coordinate information of each material point time step by time step based on the bond-based peridynamics constitutive equation, the volume information, and the group information and updating the bond stretch based on the cyclically updated coordinate information to obtain the updated bond stretch of each material point comprise:
based on the bond-based peridynamics constitutive equation, calculating acceleration of each material point at each time step of the preset total number of computational time steps, and calculating velocity and displacement of each material point at each time step based on the acceleration; wherein
an expression of the acceleration at each time step is as follows:
$$ρ a ( t ) = ρ \frac{{\partial }^{2} u ( {x}_{i} , t )}{\partial {t}^{2}} = {\int }_{{H}_{i}} f ( u ( {x}_{j} , t ) - u ( {x}_{j} , t ) , {x}_{j} - {x}_{i} ) {dV}_{j} + b ( {x}_{i} , t ) ;$$
wherein a(t) denotes acceleration of the material point i at the time step t, β denotes mass density, f denotes a force function obtained by solving the bond-based peridynamics constitutive equation, f(u(xⱼ,t)−u(xⱼ,t),xⱼ−xᵢ) denotes a force applied by the material point i to the material point j at the time step t, Vⱼ denotes a volume of the material point j, Hᵢ denotes a group of the material point i, and b(xᵢ, t) denotes external force density of the material point i at the time step t;
an expression of the velocity at each time step is as follows:
$$v ( t ) = {v}_{t - 1} + a ( t ) dt ;$$
wherein vₜ₋₁ denotes velocity at a time step t−1; and
an expression of the displacement at each time step is as follows:
$$u ( t ) = {u}_{t - 1} + v ( t ) dt ;$$
wherein uₜ₋₁ denotes velocity at the time step t−1;
based on the velocity at each time step and the displacement at each time step, updating the coordinate information of each material point;
based on the updated coordinate information, updating the relative position vector according to the expression of the relative position vector, and updating the relative displacement vector according to the expression of the relative displacement vector; and
based on updated relative position vector and updated relative displacement vector, updating the bond stretch according to the expression of the bond stretch to obtain the respective updated bond stretch of each material point.

7. The bond-based peridynamics numerical simulation method according to claim 1, wherein updating the group information based on the value of the bilinear damage function comprises that:
in a case where the value of the bilinear damage function is not equal to 0, the group information is not updated; and
in a case where the value of the bilinear damage function is equal to 0, the any two material points are mutually removed from each other's group information.

8. A computing device, comprising a memory, a processor, and a transceiver, which are interconnected via a bus; wherein the memory is configured to store a set of computer program instructions and data and transmit stored data to the processor, and the processor executes the program instructions stored in the memory to perform:
during a process of numerical simulation of material damage and fracture, acquiring quantitative discrete information of a material to be analyzed, wherein the quantitative discrete information comprises coordinate information, volume information, and group information of each material point;
randomly assigning, by using a Weibull function, a linear elastic limit bond stretch of each material point and a tensile limit bond stretch of each material point to obtain a fracture parameter matrix;
based on the coordinate information, sequentially calculating relative position vector, relative displacement vector, bond stiffness, and a bond stretch of any two material points in a group, and constructing a bilinear damage function based on the fracture parameter matrix and the bond stretch;
constructing a bond-based peridynamics constitutive equation based on the relative position vector, the relative displacement vector, the bond stretch, the bond stiffness, and the bilinear damage function;
within a preset total number of computational time steps, setting a boundary constraint and a loading mode, cyclically updating the coordinate information of each material point time step by time step based on the bond-based peridynamics constitutive equation, the volume information, and the group information, and updating the bond stretch based on cyclically updated coordinate information to obtain an updated bond stretch of each material point;
substituting the updated bond stretch into the bilinear damage function to obtain a value of the bilinear damage function, and updating the group information based on the value of the bilinear damage function to obtain updated group information; and
calculating a local damage value of each material point based on the updated group information, obtaining a damage and fracture state of the material to be analyzed at a corresponding time step of the preset total number of computational time steps based on the local damage value, and completing computation for the preset total number of computational time steps through iterative looping to obtain a bond-based peridynamics simulation result for damage and fracture behavior of the material to be analyzed.

9. The computing device according to claim 8, wherein acquiring the quantitative discrete information of the material to be analyzed comprises:
acquiring numerical values of mechanical parameters required for bond-based peridynamics numerical simulation, wherein the mechanical parameters at least comprise elastic modulus, density, Poisson's ratio, geometric dimension, and material point size of the material to be analyzed;
performing a quantitative discrete processing on the material to be analyzed based on the material point size to obtain the coordinate information and the volume information of each material point; and
for each material point, designating neighboring material points within a predefined domain radius as a group of each material point, and acquiring and storing group information of the group.

10. The computing device according to claim 9, wherein randomly assigning, by using the Weibull function, the linear elastic limit bond stretch of each material point and the tensile limit bond stretch of each material point to obtain the fracture parameter matrix comprises:
constructing a first matrix of a same size as a number of material points, and randomly assigning values to the first matrix using the Weibull function;
acquiring an experimental value of a linear elastic limit bond stretch and an experimental value of a tensile limit bond stretch of the material to be analyzed, taking a product of a randomly assigned first matrix and the experimental value of the linear elastic limit bond stretch as a linear elastic limit bond stretch matrix of each material point, and taking a product of the randomly assigned first matrix and the experimental value of the tensile limit bond stretch as a tensile limit bond stretch matrix of each material point; and
taking the linear elastic limit bond stretch matrix and the tensile limit bond stretch matrix as a fracture parameter matrix.

11. The computing device according to claim 10, wherein based on the coordinate information, sequentially calculating the relative position vector, the relative displacement vector, the bond stiffness, and the bond stretch of the any two material points in the group and constructing the bilinear damage function based on the fracture parameter matrix and the bond stretch comprise:
calculating the relative position vector, the relative displacement vector, and the bond stiffness between the any two material points based on initial coordinate information;
wherein an expression of the relative position vector is as follows:
$$ξ = {x}_{j} - {x}_{i} ;$$
wherein xⱼ denotes coordinates of a material point j, and xᵢ denotes coordinates of a material point i;
an expression of the relative displacement vector is as follows:
$$η = u ( {x}_{j} , t ) - u ( {x}_{i} , t ) ;$$
wherein u(xⱼ,t) denotes displacement vector of the material point j at a time step t, and u(xᵢ,t) denotes displacement vector of the material point i at the time step t; and
an expression of the bond stiffness is as follows:
$$c = \{ \begin{matrix}\frac{12 E}{\text{?}} & three - dimensional condition \\ \frac{9 E}{\text{?}} & plane stress condition \\ \frac{\text{?} E}{\text{?}} & plane strain condition \\ \frac{2 E}{\text{?}} & one - dimensional condition\end{matrix} ,$$
$$\text{?} \text{indicates text missing or illegible when filed}$$
E denotes elastic modulus, and δ denotes a domain radius;
calculating the bond stretch based on the relative position vector and relative displacement vector, wherein an expression of the bond stretch is as follows:
$$s = \frac{‖ ξ + η ‖ - ‖ ζ ‖}{‖ ξ ‖} ;$$
and
contracting the bilinear damage function based on the linear elastic limit bond stretch of each material point and the tensile limit bond stretch of each material point in the fracture parameter matrix and the bond stretch, wherein the bilinear damage function is as follows:
$$D = \{ \begin{matrix}1 & 0 < s \leq {s}_{p} \\ \frac{Δ OFB}{Δ OAB} & {s}_{p} < s \leq {s}_{r} \\ 0 & {s}_{r} < s\end{matrix} ;$$
wherein sₚ denotes the linear elastic limit bond stretch of each material point, sᵣ denotes the tensile limit bond stretch of each material point, ΔOFB denotes an area of a triangle composed of an unloading path after damage, a continuous loading path after damage, and the tensile limit bond stretch in a damage fracture process, and ΔOAB denotes an area of a triangle composed of a loading and unloading path in an elastic stage, the continuous loading path after damage, and the unloading path after damage in the damage fracture process.

12. The computing device according to claim 11, wherein the bond-based peridynamics constitutive equation is as follows:
$$f ( η , ξ ) = Dc ( 0 , δ ) s \frac{ξ + η}{\vert ξ + η \vert} ;$$
wherein D denotes the bilinear damage function, ξ denotes the relative position vector, η denotes the relative displacement vector, δ denotes the domain radius, s denotes the bond stretch, and c(0,δ) denotes the bond stiffness.

13. The computing device according to claim 12, wherein cyclically updating the coordinate information of each material point time step by time step based on the bond-based peridynamics constitutive equation, the volume information, and the group information and updating the bond stretch based on the cyclically updated coordinate information to obtain the updated bond stretch of each material point comprise:
based on the bond-based peridynamics constitutive equation, calculating acceleration of each material point at each time step of the preset total number of computational time steps, and calculating velocity and displacement of each material point at each time step based on the acceleration; wherein
an expression of the acceleration at each time step is as follows:
$$ρ a ( t ) = ρ \frac{{\partial }^{2} u ( {x}_{i} , t )}{\partial {t}^{2}} = {\int }_{{H}_{i}} f ( u ( {x}_{j} , t ) - u ( {x}_{j} , t ) , {x}_{j} - {x}_{i} ) {dV}_{j} + b ( {x}_{i} , t ) ;$$
wherein a(t) denotes acceleration of the material point i at the time step t, ρ denotes mass density, f denotes a force function obtained by solving the bond-based peridynamics constitutive equation, f(u(xⱼ,t)−u(xⱼ,t),xⱼ−xᵢ) denotes a force applied by the material point i to the material point j at the time step t, Vⱼ denotes a volume of the material point j, Hᵢ denotes a group of the material point i, and b (xⱼ,t) denotes external force density of the material point i at the time step t;
an expression of the velocity at each time step is as follows:
$$v ( t ) = {v}_{t - 1} + a ( t ) dt ;$$
wherein vₜ₋₁ denotes velocity at a time step t−1; and
an expression of the displacement at each time step is as follows:
$$u ( t ) = {u}_{t - 1} + v ( t ) dt ;$$
wherein uₜ₋₁ denotes velocity at the time step t−1;
based on the velocity at each time step and the displacement at each time step, updating the coordinate information of each material point;
based on the updated coordinate information, updating the relative position vector according to the expression of the relative position vector, and updating the relative displacement vector according to the expression of the relative displacement vector; and
based on updated relative position vector and updated relative displacement vector, updating the bond stretch according to the expression of the bond stretch to obtain the respective updated bond stretch of each material point.

14. The computing device according to claim 8, wherein updating the group information based on the value of the bilinear damage function comprises that:
in a case where the value of the bilinear damage function is not equal to 0, the group information is not updated; and
in a case where the value of the bilinear damage function is equal to 0, the any two material points are mutually removed from each other's group information.

15. A non-transitory computer-readable storage medium storing a computer program that, when executed, performs the bond-based peridynamics numerical simulation method according to claim 1.
